(19) United States
(12) Patent Application Publication
(10) Pub. No.: US 2025/0311260 A1
(43) Pub. Date: Oct. 2, 2025

(54) SEMICONDUCTOR DEVICE

(71) Applicant: Mitsubishi Electric Corporation, Tokyo (JP)

(72) Inventors: Reona FURUKAWA, Tokyo (JP); Koji TANAKA, Tokyo (JP); Takahiro NAKATANI, Tokyo (JP); Kosuke SAKAGUCHI, Tokyo (JP)

(73) Assignee: Mitsubishi Electric Corporation, Tokyo (JP)

(21) Appl. No.: 19/004,146

(22) Filed: Dec. 27, 2024

(30) Foreign Application Priority Data
Mar. 27, 2024 (JP) 2024-050907

(51) Int. Cl. H10D 12/00; H10D 64/00; H10D 84/00

(52) U.S. Cl. CPC H10D 12/481; H10D 64/117; H10D 84/161

(57) ABSTRACT

A semiconductor device includes: a first-1 trench gate structure, a first-2 trench gate structure, and a barrier structure provided in a first trench; a second trench gate structure provided in a second trench; and a third trench gate structure provided in a third trench and connected to the first-2 trench gate structure and the second trench gate structure. The barrier structure includes an insulating film provided at least partially between the first-1 upper electrode and the first-2 upper electrode and insulating the first-1 upper electrode and the first-2 upper electrode.

### BACKGROUND OF THE INVENTION

### Field of the Invention

The present disclosure relates to semiconductor devices.

### Description of the Background Art

A two-stage gate semiconductor device having an active trench and a dummy trench is known. For example, in a semiconductor device disclosed in Japanese Patent Application Laid-Open No. 2023-39138, upper and lower electrodes in an active trench are both connected to a gate electrode to be at a gate potential, and an upper electrode in a dummy trench is connected to an emitter electrode to be at a dummy potential and a lower electrode in the dummy trench is connected to the gate electrode to be at the gate potential.

A semiconductor device as described above, however, has a problem in that, when an active trench in which an upper electrode is at a gate potential and a dummy trench in which an upper electrode is at a dummy potential are arranged, any of the upper electrodes cannot be maintained at a proper potential.

### SUMMARY

The present disclosure has been conceived in view of a problem as described above, and it is an object of the present disclosure to provide technology enabling maintenance of upper electrodes at proper potentials.

A semiconductor device according to the present disclosure includes: a semiconductor substrate having a first trench, a second trench, and a third trench, the first trench extending in a first direction, the second trench extending along the first trench in the first direction, the third trench extending in a second direction different from the first direction and being connected to the first trench and the second trench; a first-1 trench gate structure and a first-2 trench gate structure provided in the first trench; a barrier structure provided in the first trench and between the first-1 trench gate structure and the first-2 trench gate structure; a second trench gate structure provided in the second trench; and a third trench gate structure provided in the third trench and connected to the first-2 trench gate structure and the second trench gate structure. The first-1 trench gate structure includes: a first lower electrode; and a first-1 upper electrode insulated from the first lower electrode and provided above the first lower electrode, the first-2 trench gate structure includes: the first lower electrode; and a first-2 upper electrode insulated from the first lower electrode and provided above the first lower electrode, the barrier structure includes: the first lower electrode; and an insulating film provided at least partially between the first-1 upper electrode and the first-2 upper electrode and insulating the first-1 upper electrode and the first-2 upper electrode, the second trench gate structure includes: a second lower electrode; and a second upper electrode insulated from the second lower electrode and provided above the second lower electrode, the third trench gate structure includes: a third lower electrode electrically connecting the first lower electrode and the second lower electrode; and a third upper electrode electrically connecting the first-2 upper electrode and the second upper electrode, insulated from the third lower electrode, and provided above the third lower electrode, the first lower electrode, the second lower electrode, the third lower electrode, the first-2 upper electrode, the second upper electrode, and the third upper electrode are electrically connected to one of a gate electrode and a dummy electrode, and the first-1 upper electrode is electrically connected to the other one of the gate electrode and the dummy electrode.

The upper electrodes can be maintained at proper potentials.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a configuration of a semiconductor device according to Embodiment 1;

FIG. 2 is a cross-sectional view illustrating a configuration of the semiconductor device according to Embodiment 1;

FIG. 3 is a cross-sectional view illustrating a configuration of the semiconductor device according to Embodiment 1;

FIG. 4 is a cross-sectional view illustrating a configuration of the semiconductor device according to Embodiment 1;

FIG. 5 is a plan view illustrating a configuration of a semiconductor device according to Embodiment 2;

FIG. 6 is a cross-sectional view illustrating a configuration of the semiconductor device according to Embodiment 2;

FIG. 7 is a cross-sectional view illustrating a configuration of the semiconductor device according to Embodiment 2;

FIG. 8 is a plan view illustrating a configuration of a semiconductor device according to Embodiment 3;

FIG. 9 is a cross-sectional view illustrating a configuration of the semiconductor device according to Embodiment 3;

FIG. 10 is a cross-sectional view illustrating a configuration of the semiconductor device according to Embodiment 3;

FIG. 11 is a schematic plan view illustrating a configuration of a semiconductor device according to Embodiment 4;

FIG. 12 is a plan view illustrating a configuration of the semiconductor device according to Embodiment 4;

FIG. 13 is a cross-sectional view illustrating a configuration of the semiconductor device according to Embodiment 4;

FIG. 14 is a cross-sectional view illustrating a configuration of a semiconductor device according to Embodiment 5; and

FIG. 15 is a cross-sectional view illustrating a configuration of a semiconductor device according to Embodiment 6.

### DESCRIPTION OF THE PREFERRED EMBODIMENTS

Embodiments will be described below with reference to the accompanying drawings Features described in the embodiments below are examples, and all the features are not necessarily required. In description made below, similar components in the embodiments bear the same or similar reference signs, and different components will mainly be described. In description made below, specific positions and directions, such as “upper”, “lower”, “left”, “right”, “front”, and “back”, may not necessarily match positions and directions in actual implementation.

### Embodiment 1

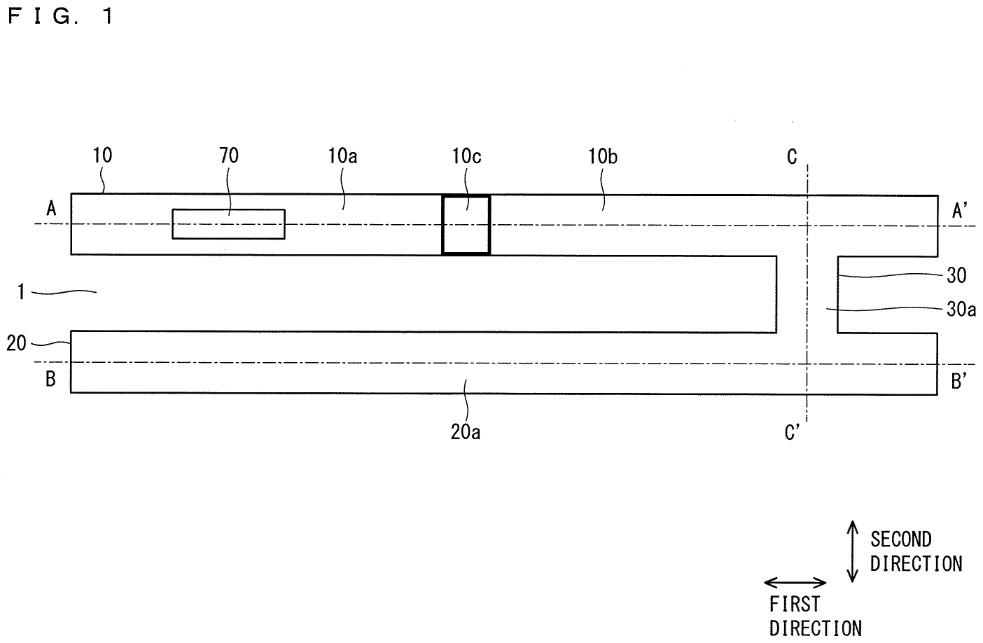

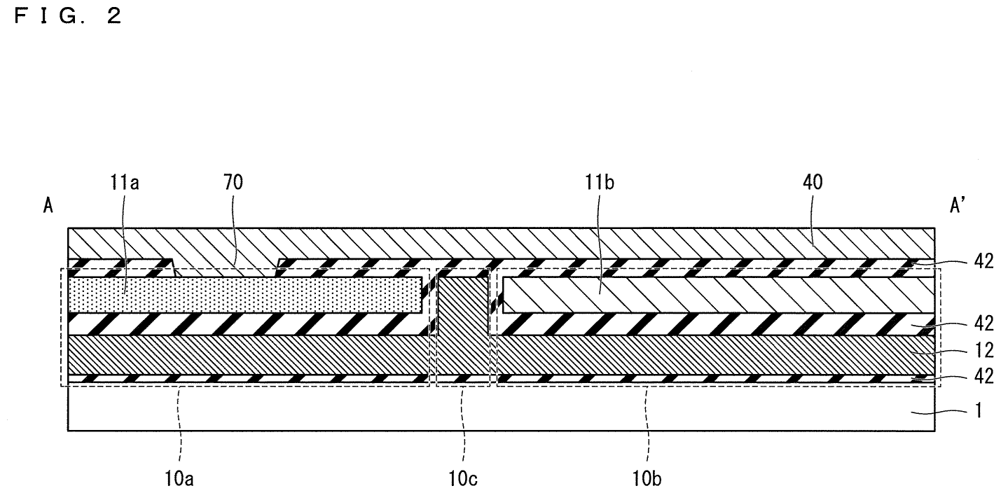

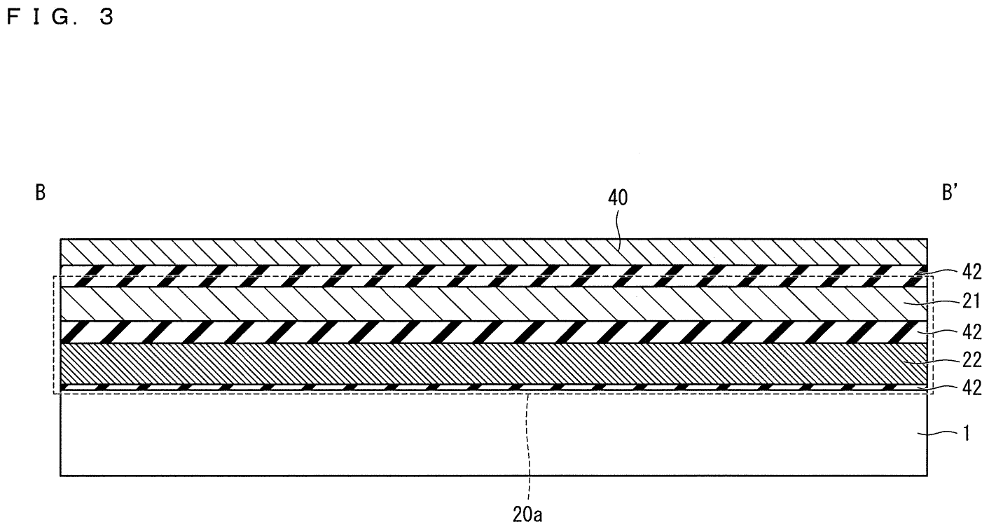

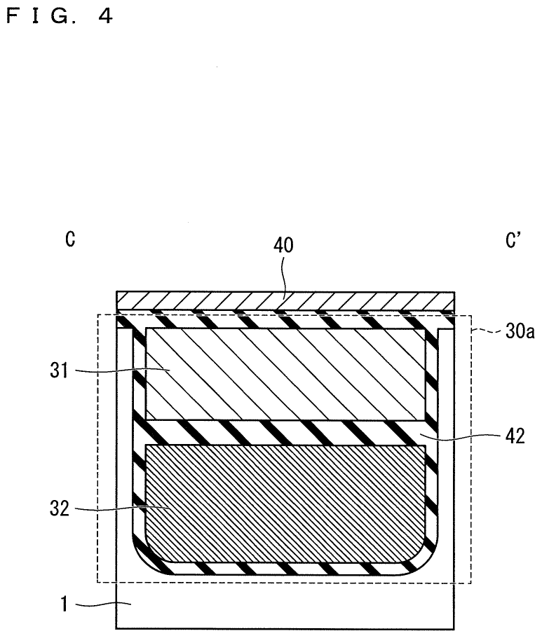

FIG. 1 is a plan view illustrating a configuration of a semiconductor device according to Embodiment 1. FIG. 2 is a cross-sectional view taken along the line A-A′ of FIG. 1, FIG. 3 is a cross-sectional view taken along the line B-B′ of FIG. 1, and FIG. 4 is a cross-sectional view taken along the line C-C′ of FIG. 1.

The semiconductor device according to Embodiment 1 includes a semiconductor substrate 1, a D trench gate structure 10a as a first-1 trench gate structure, a first A trench gate structure 10b as a first-2 trench gate structure, a second A trench gate structure 20a as a second trench gate structure, a third A trench gate structure 30a as a third trench gate structure, and a barrier structure 10c.

The semiconductor substrate 1 may include a normal semiconductor wafer or may include an epitaxially grown layer. A material for the semiconductor substrate 1 may be silicon (Si) as normal or may be a wide bandgap semiconductor, such as silicon carbide (SiC), gallium nitride (GaN), and diamond. The semiconductor substrate 1 formed of the wide bandgap semiconductor enables stable operation at a high temperature and at a high voltage and a faster switching speed of the semiconductor device.

As illustrated in FIG. 1, the semiconductor substrate 1 has a D trench 10 as a first trench, an A trench 20 as a second trench, and an S trench 30 as a third trench. The D trench 10 extends in a first direction, and the A trench 20 extends along the D trench 10 in the first direction. The S trench 30 extends in a second direction different from the first direction and is connected to the D trench 10 and the A trench 20. While the second direction is a direction orthogonal to the first direction in Embodiment 1, the second direction is not limited to this direction.

### <D Trench 10>

As illustrated in FIGS. 1 and 2, the D trench gate structure 10a, the first A trench gate structure 10b, and the barrier structure 10c are provided in the D trench 10. The barrier structure 10c is provided between the D trench gate structure 10a and the first A trench gate structure 10b.

As illustrated in FIG. 2, the D trench gate structure 10a as an AD structure includes an A lower electrode 12 as an electrode having an active function, a D upper electrode 11a as an electrode having a dummy function, and an insulating film 42. That is to say, in Embodiment 1, a first lower electrode is the A lower electrode 12, and a first-1 upper electrode is the D upper electrode 11a. The D upper electrode 11a is insulated from the A lower electrode 12 by the insulating film 42 and is provided above the A lower electrode 12.

The first A trench gate structure 10b as an AA structure includes the A lower electrode 12 as the electrode having the active function, an A upper electrode 11b as the electrode having the active function, and the insulating film 42. That is to say, in Embodiment 1, a first-2 upper electrode is the A upper electrode 11b. The A upper electrode 11b is insulated from the A lower electrode 12 by the insulating film 42 and is provided above the A lower electrode 12.

The barrier structure 10c, which will be described in detail below, includes the A lower electrode 12 as the electrode having the active function and the insulating film 42.

The electrode having the active function is a potentially active electrode electrically connected to an actively controllable gate electrode and is an electrode at a potential controllable according to a gate signal. The gate electrode may include a gate pad. On the other hand, the electrode having the dummy function is an electrode connected to a dummy electrode at a potential uncontrollable according to the gate signal. While the dummy electrode is an emitter electrode 40 electrically connected to the D upper electrode 11a via a contact region 70 in an example of FIG. 2, the dummy electrode may be any electrode at uncontrollable electricity and, for example, may be an electrically floating electrode.

A letter “A” attached to each of the first A trench gate structure 10b, the A lower electrode 12, and the like means that they are the trench gate structure and the electrode having the active function. On the other hand, a letter “D” attached to each of the D trench gate structure 10a, the D upper electrode 11a, and the like means that they are the trench gate structure and the electrode having the dummy function. The trench gate structure having the active function does not necessarily contribute to control of energization of a main current flowing between an emitter and a collector (i.e., formation of a channel in the semiconductor substrate 1).

Whether the trench gate structure contributes to control of energization of the main current is determined by a state of the semiconductor substrate 1 around the trench gate structure and a potential of an upper electrode of the trench gate structure. Conditions of the state of the semiconductor substrate 1 for the trench gate structure to contribute to control of energization of the main current include: (i) a base layer of a first conductivity type (e.g., a P type) at the same height as the upper electrode in a trench opposes the upper electrode with an insulating film therebetween; and (ii) an emitter layer of a second conductivity type (e.g., an N type) connected to an emitter electrode is provided on the base layer, and a drift layer of the second conductivity type (e.g., N type) is provided under the base layer. A condition of the potential of the upper electrode for the trench gate structure to contribute to control of energization of the main current includes (iii) a gate signal can be input into the upper electrode, that is, the upper electrode is an electrode having the active function.

The D upper electrode 11a is the electrode having the dummy function, so that the D trench gate structure 10a does not meet (iii) and does not contribute to control of energization of the main current. The A upper electrode 11b is the electrode having the active function, so that the first A trench gate structure 10b meets (iii) but does not meet (i) or (ii) and thus does not contribute to control of energization of the main current. The barrier structure 10c also does not meet (i) or (ii) and thus does not contribute to control of energization of the main current. The structures in the D trench 10 thus do not contribute to control of energization of the main current.

The barrier structure 10c includes the A lower electrode 12 and the insulating film 42 as described above. The insulating film 42 is provided partially between the D upper electrode 11a and the A upper electrode 11b and insulates the D upper electrode 11a and the A upper electrode 11b. In Embodiment 1, the A lower electrode 12 of the barrier structure 10c extends to a top of the D trench 10, and a top of the A lower electrode 12 of the barrier structure 10c is at the same height as a top of the D upper electrode 11a and a top of the A upper electrode 11b. A portion of the A lower electrode 12 extending to the top of the D trench 10 is insulated from each of the D upper electrode 11a and the A upper electrode 11b by the insulating film 42.

### <A Trench 20>

As illustrated in FIGS. 1 and 3, the second A trench gate structure 20a is provided in the A trench 20.

As illustrated in FIG. 3, the second A trench gate structure 20a as the AA structure includes an A lower electrode 22 as an electrode having the active function, an A upper electrode 21 as an electrode having the active function, and the insulating film 42. That is to say, in Embodiment 1, a second lower electrode is the A lower electrode 22, and a second upper electrode is the A upper electrode 21. The A upper electrode 21 is insulated from the A lower electrode 22 by the insulating film 42 and is provided above the A lower electrode 22.

The second A trench gate structure 20a meets (i) to (iii) above and thus contributes to control of energization of the main current. At least part of the structure in the A trench 20 thus functions as a gate of at least any one of a metal oxide semiconductor field effect transistor (MOSFET), an insulated gate bipolar transistor (IGBT), and a reverse conducting-IGBT (RC-IGBT). At least any one of A, B, C, . . . , and Z herein means any one of all combinations of one or more elements extracted from A, B, C, . . . , and Z, for example.

### <S Trench 30>

As illustrated in FIGS. 1 and 4, the third A trench gate structure 30a is provided in the S trench 30.

As illustrated in FIG. 4, the third A trench gate structure 30a as the AA structure includes an A lower electrode 32 as an electrode having the active function, an A upper electrode 31 as an electrode having the active function, and the insulating film 42. That is to say, in Embodiment 1, a third lower electrode is the A lower electrode 32, and a third upper electrode is the A upper electrode 31. The A upper electrode 31 is insulated from the A lower electrode 32 by the insulating film 42 and is provided above the A lower electrode 32.

The A lower electrode 32 electrically connects the A lower electrode 12 of the first A trench gate structure 10b and the A lower electrode 22 of the second A trench gate structure 20a. The A upper electrode 31 electrically connects the A upper electrode 11b of the first A trench gate structure 10b and the A upper electrode 21 of the second A trench gate structure 20a. That is to say, the electrodes in the D trench 10 and the electrodes in the A trench 20 are electrically connected by the electrodes in the S trench 30. The structure in the S trench 30 may or may not contribute to control of energization of the main current.

### <Summary of Embodiment 1>

In Embodiment 1, the insulating film 42 of the barrier structure 10c is provided partially between the D upper electrode 11a and the A upper electrode 11b and insulates the D upper electrode 11a and the A upper electrode 11b. According to such a configuration, the A upper electrode 11b electrically separated from the D upper electrode 11a by the barrier structure 10c can electrically be connected to the A upper electrode 31 in the S trench 30. Thus, the A upper electrode 11b and the D upper electrode 11a are maintained at proper potentials while an electrical short between the A upper electrode 11b and the D upper electrode 11a is avoided, and the A upper electrode 11b can be at a gate potential of the gate electrode.

According to such a configuration, the potential of the A upper electrode 11b in the D trench 10 can be controlled by the barrier structure 10c provided in the D trench 10 and the third A trench gate structure 30a in the S trench 30. This can improve reliability or design freedom (freedom of placement of gate wiring) because, even when breakage occurs in a particular trench, electrical connection can be maintained by another trench.

### <Modifications>

In Embodiment 1, the first lower electrode, the second lower electrode, the third lower electrode, the first-2 upper electrode, the second upper electrode, and the third upper electrode are respectively the A lower electrode 12, the A lower electrode 22, the A lower electrode 32, the A upper electrode 11b, the A upper electrode 21, and the A upper electrode 31 electrically connected to the gate electrode. The first-1 upper electrode is the D upper electrode 11a electrically connected to the dummy electrode.

Connections to the gate electrode and the dummy electrode, however, may be reversed. That is to say, the first lower electrode, the second lower electrode, the third lower electrode, the first-2 upper electrode, the second upper electrode, and the third upper electrode may be electrodes having the dummy function electrically connected to the emitter electrode. The first-1 upper electrode may be an electrode having the active function electrically connected to the gate electrode.

### Embodiment 2

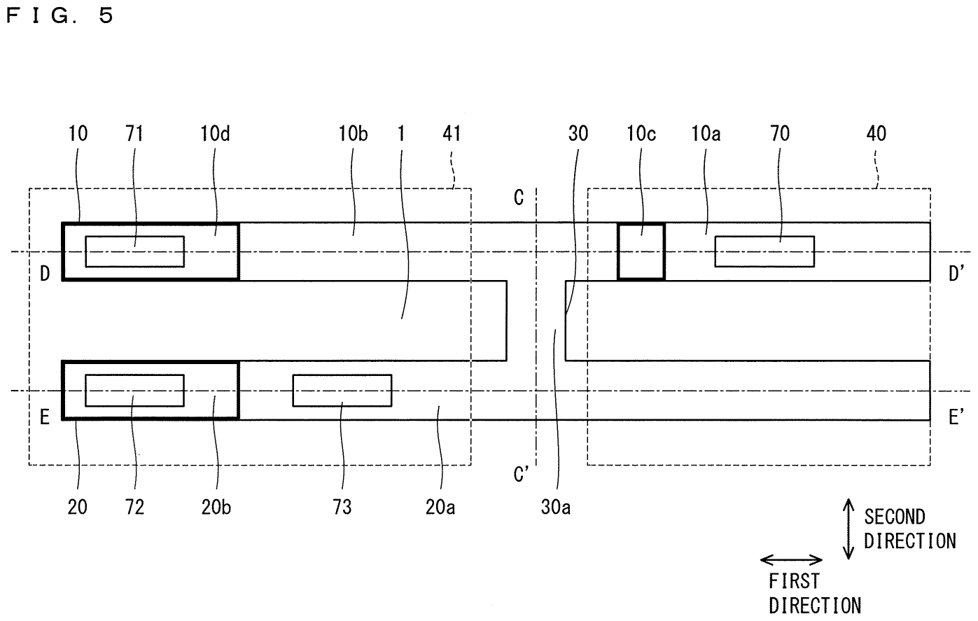

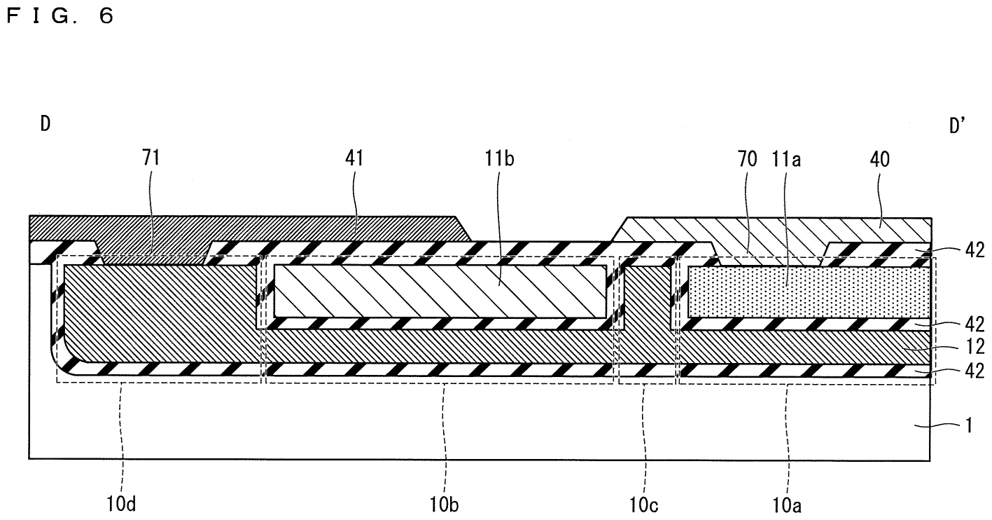

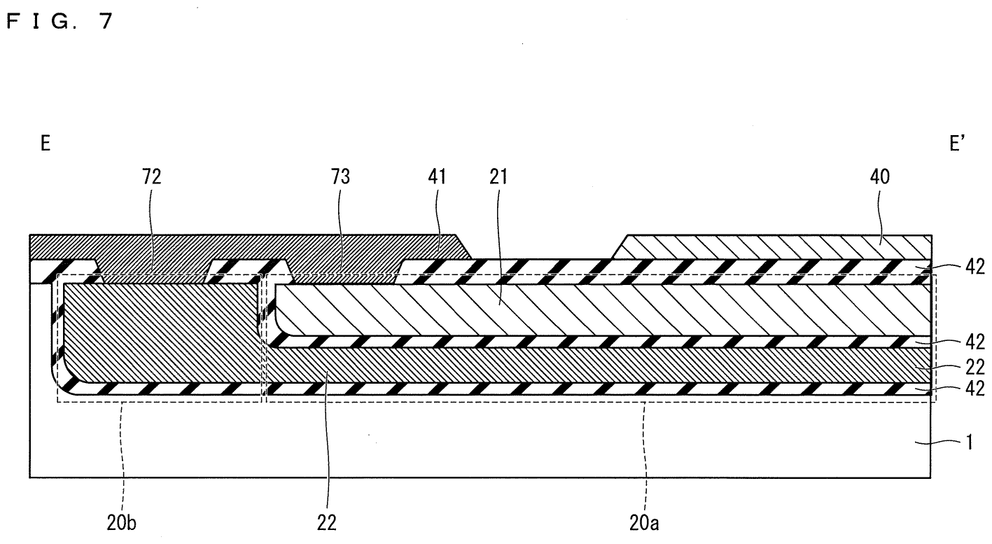

FIG. 5 is a plan view illustrating a configuration of a semiconductor device according to Embodiment 2. FIG. 6 is a cross-sectional view taken along the line D-D′ of FIG. 5, and FIG. 7 is a cross-sectional view taken along the line E-E′ of FIG. 5. A cross-sectional view taken along the line C-C′ of FIG. 5 is similar to that in FIG. 4 except that the emitter electrode 40 is not provided over the insulating film 42.

As illustrated in FIGS. 5 to 7, in Embodiment 2, a lower-stage lifting structure 10d is provided in the D trench 10, and a lower-stage lifting structure 20b is provided in the A trench 20 in addition to the configuration described in Embodiment 1.

As illustrated in FIG. 6, in the lower-stage lifting structure 10d, the A lower electrode 12 extends to the top of the D trench 10 and is connected to a gate electrode 41 via a contact region 71. As illustrated in FIGS. 5 and 6, the lower-stage lifting structure 10d, the first A trench gate structure 10b, the barrier structure 10c, and the D trench gate structure 10a are arranged in this order in the first direction.

As illustrated in FIG. 7, in the lower-stage lifting structure 20d, the A lower electrode 22 extends to a top of the A trench 20 and is electrically connected to the gate electrode 41 via the contact region 72. The A upper electrode 21 is connected to the gate electrode 41 via a contact region 73. As illustrated in FIGS. 5 and 7, the lower-stage lifting structure 20b and the second A trench gate structure 20a are arranged in the first direction.

According to the semiconductor device according to Embodiment 2 as described above, in the lower-stage lifting structure 10d, the A lower electrode 12 extends to the top of the D trench 10 and is connected to the gate electrode 41 via the contact region 71. According to such a configuration, even when the A lower electrode 22 in the A trench 20 is not electrically connected to the gate electrode 41 via the contact region 72 for any reason, the A lower electrode 22 in the A trench 20 can electrically be connected to the gate electrode 41 via the A lower electrode 12 in the D trench 10.

### Embodiment 3

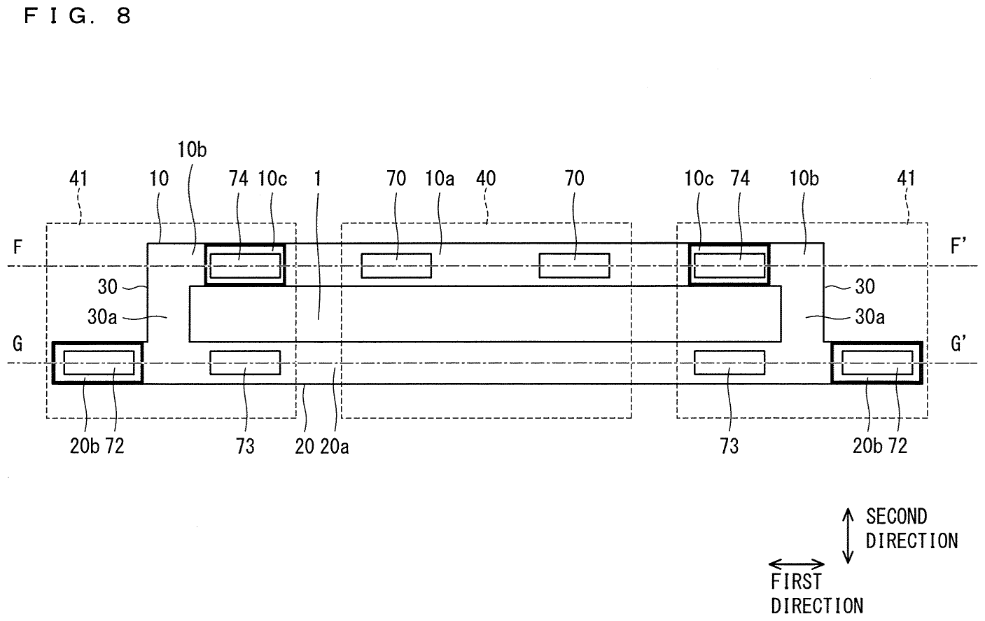

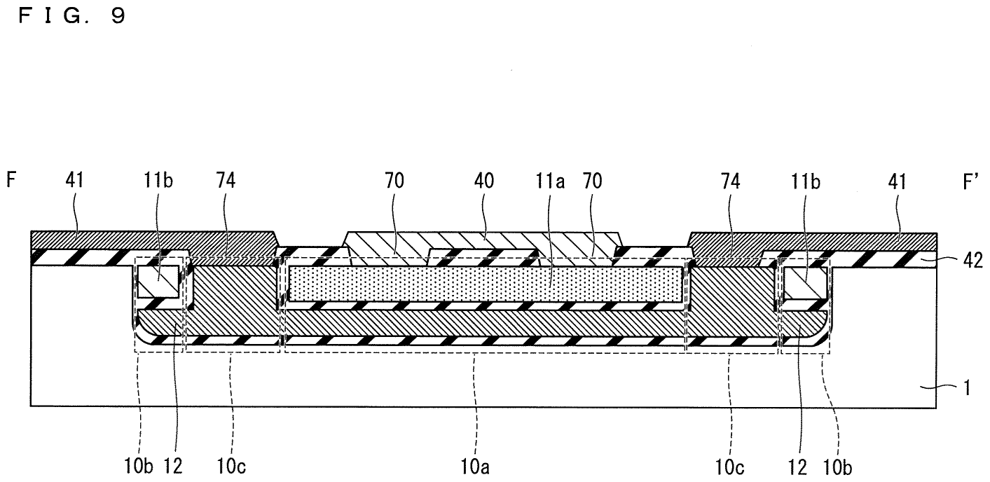

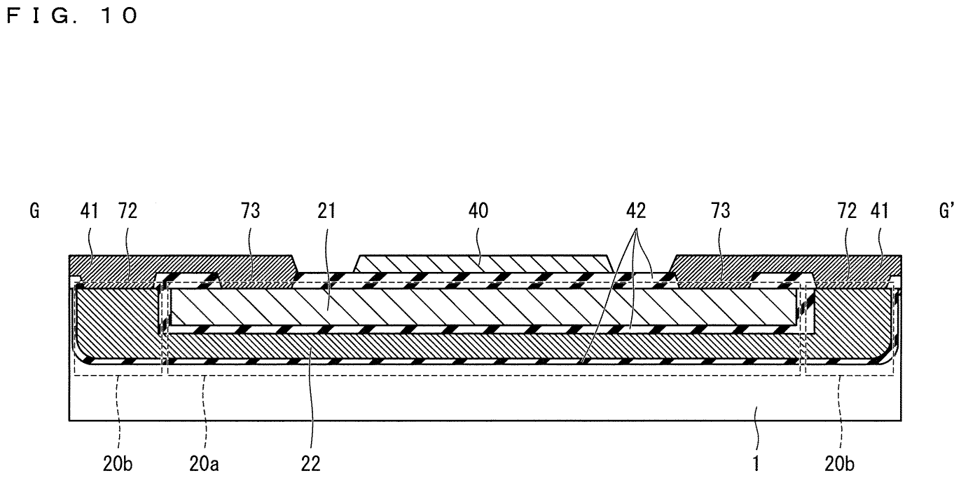

FIG. 8 is a plan view illustrating a configuration of a semiconductor device according to Embodiment 3. FIG. 9 is a cross-sectional view taken along the line F-F′ of FIG. 8, and FIG. 10 is a cross-sectional view taken along the line G-G′ of FIG. 8.

In Embodiment 3, as illustrated in FIG. 9, a portion of the A lower electrode 12 of the barrier structure 10c protruding to the top of the D trench 10 is electrically connected to the gate electrode 41 via a contact region 74. That is to say, the A lower electrode 12 of the barrier structure 10c extends through the insulating film 42 to the top of the D trench 10 and is electrically connected to the gate electrode 41.

According to such a configuration, even when the A lower electrode 22 in the A trench 20 is not electrically connected to the gate electrode 41 via the contact region 72 for any reason, the A lower electrode 22 in the A trench 20 can electrically be connected to the gate electrode 41 via the barrier structure 10c. While the A lower electrode 12 of the barrier structure 10c is electrically connected to the gate electrode 41 in Embodiment 3, the A lower electrode 12 of the barrier structure 10c may electrically be connected to the dummy electrode in the above-mentioned modification.

### Embodiment 4

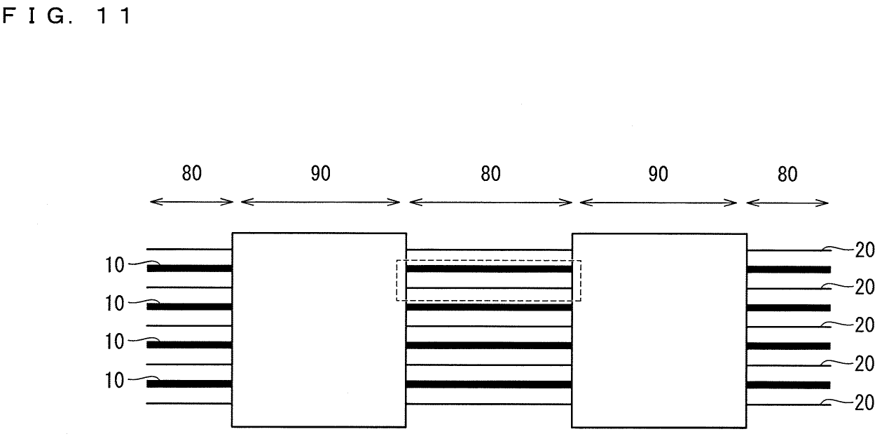

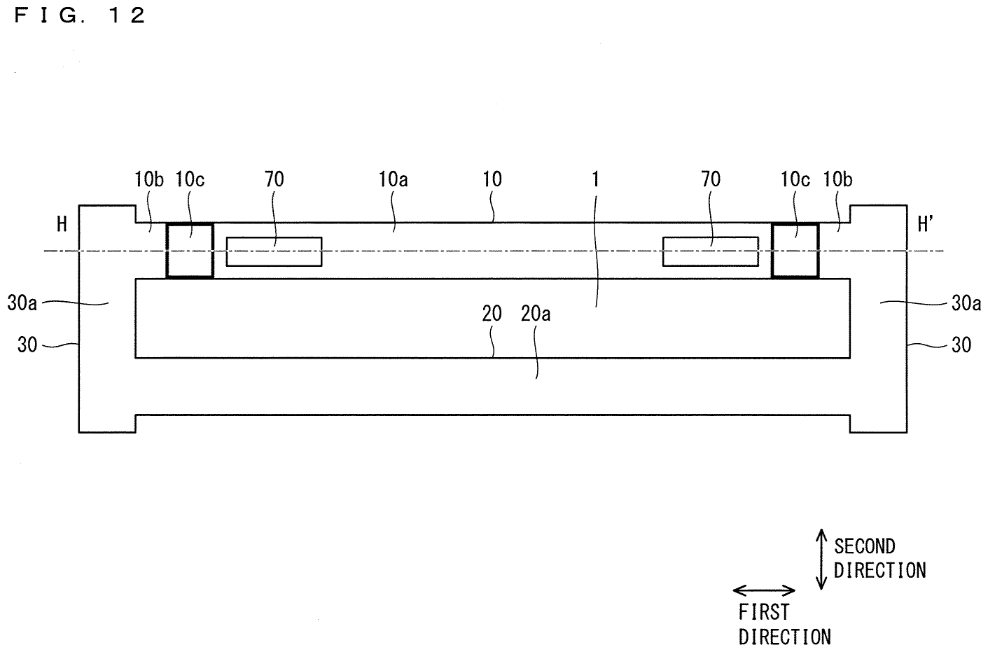

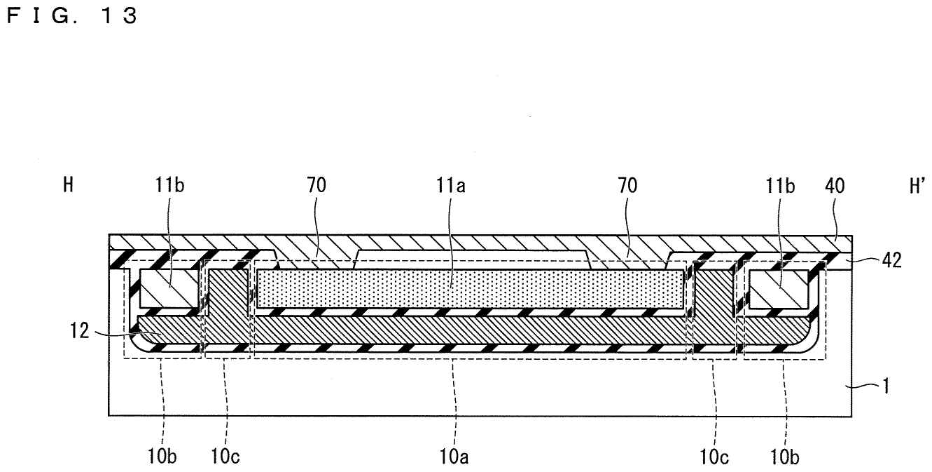

FIG. 11 is a schematic plan view illustrating a configuration of a semiconductor device according to Embodiment 4. FIG. 12 is a plan view of a dotted square portion in FIG. 11, and FIG. 13 is a cross-sectional view taken along the line H-H′ of FIG. 12.

As illustrated in FIG. 11, the semiconductor device according to Embodiment 4 is an RC-IGBT, and an IGBT region 80 having a function of an IGBT and two or more island-type diode regions 90 each having a function of a diode are provided in a single semiconductor substrate 1. The IGBT region 80 is provided between two diode regions 90. The diode includes at least any one of a Schottky barrier diode (SBD) and a PN junction diode (PND).

As illustrated in FIGS. 11 and 12, the IGBT region 80 includes components similar to the components described in Embodiment 1. As illustrated in FIGS. 11 to 13, one of the diode region 90, one of the first A trench gate structure 10b, one of the barrier structure 10c, the D trench gate structure 10a, another of the barrier structure 10c, another of the first A trench gate structure 10b, and another of the diode region 90 are arranged in this order in the first direction. According to such a configuration, the D trench 10 and the A trench 20 can be maintained at proper potentials between the island-type diode regions 90 of the RC-IGBT.

While the D upper electrode 11a is electrically connected to the emitter electrode 40 via two contact regions 70 in an example of FIGS. 12 and 13, the D upper electrode 11a may electrically be connected to the emitter electrode 40 via one contact region 70 or three or more contact regions 70.

### Embodiment 5

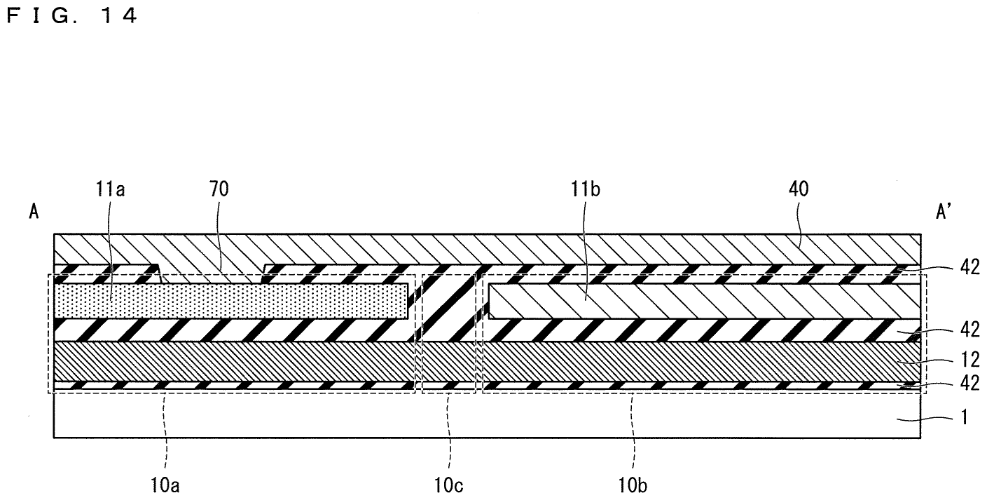

FIG. 14 is a cross-sectional view illustrating a configuration of a semiconductor device according to Embodiment 5 and corresponds to the cross-sectional view in FIG. 2. In Embodiment 5, the insulating film 42 of the barrier structure 10c is provided entirely between the D upper electrode 11a and the A upper electrode 11b. According to such a configuration, insulation reliability of the semiconductor device can be increased between the D upper electrode 11a and the A upper electrode 11b.

### Embodiment 6

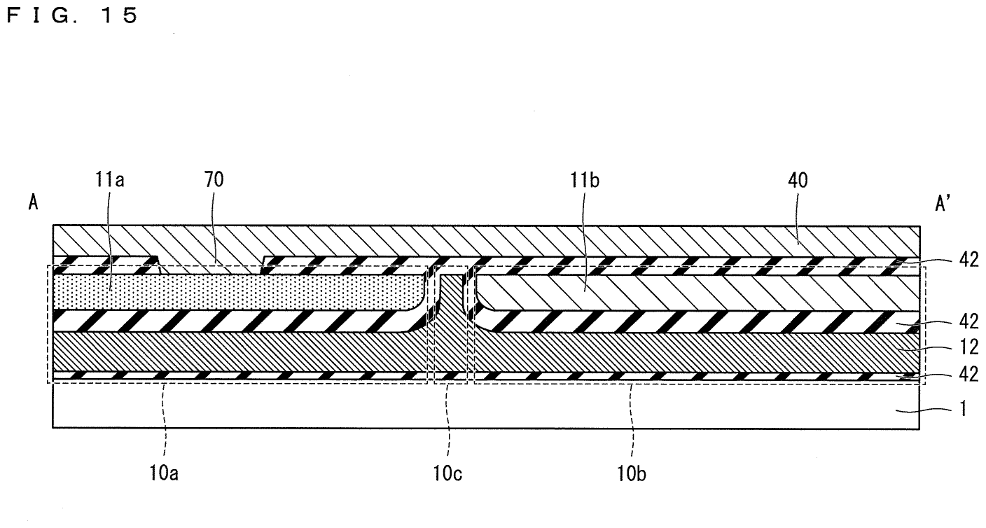

FIG. 15 is a cross-sectional view illustrating a configuration of a semiconductor device according to Embodiment 6 and corresponds to the cross-sectional view in FIG. 2. In Embodiment 6, at least any one of a portion in contact with a side and a bottom of the D upper electrode 11a and a portion in contact with a side and a bottom of the A upper electrode 11b of the insulating film 42 of the barrier structure 10c is rounded in a cross-sectional view. According to such a configuration, local application of an electric field to the insulating film 42 can be suppressed, so that insulation reliability of the semiconductor device can be increased.

In the present disclosure in English, indefinite articles “a” and “an” mean one or more. Thus, “a”, “an”, “one or more”, and “at least one” can be used interchangeably.

Embodiments and modifications can freely be combined with each other and can be modified or omitted as appropriate.

Various aspects of the present disclosure will collectively be described below as appendices.

### (Appendix 1)

A semiconductor device comprising:
a semiconductor substrate having a first trench, a second trench, and a third trench, the first trench extending in a first direction, the second trench extending along the first trench in the first direction, the third trench extending in a second direction different from the first direction and being connected to the first trench and the second trench;
a first-1 trench gate structure and a first-2 trench gate structure provided in the first trench;
a barrier structure provided in the first trench and between the first-1 trench gate structure and the first-2 trench gate structure;
a second trench gate structure provided in the second trench; and
a third trench gate structure provided in the third trench and connected to the first-2 trench gate structure and the second trench gate structure, wherein
the first-1 trench gate structure comprises:
   a first lower electrode; and
   a first-1 upper electrode insulated from the first lower electrode and provided above the first lower electrode,
the first-2 trench gate structure comprises:
   the first lower electrode; and
   a first-2 upper electrode insulated from the first lower electrode and provided above the first lower electrode,
the barrier structure comprises:
   the first lower electrode; and
   an insulating film provided at least partially between the first-1 upper electrode and the first-2 upper electrode and insulating the first-1 upper electrode and the first-2 upper electrode,
the second trench gate structure comprises:
   a second lower electrode; and
   a second upper electrode insulated from the second lower electrode and provided above the second lower electrode,
the third trench gate structure comprises:
   a third lower electrode electrically connecting the first lower electrode and the second lower electrode; and
   a third upper electrode electrically connecting the first-2 upper electrode and the second upper electrode, insulated from the third lower electrode, and provided above the third lower electrode,
the first lower electrode, the second lower electrode, the third lower electrode, the first-2 upper electrode, the second upper electrode, and the third upper electrode are electrically connected to one of a gate electrode and a dummy electrode, and
the first-1 upper electrode is electrically connected to the other one of the gate electrode and the dummy electrode.

### (Appendix 2)

The semiconductor device according to Appendix 1, further comprising
a lower-stage lifting structure which is provided in the first trench and in which the first lower electrode extends to a top of the first trench, wherein
the lower-stage lifting structure, the first-2 trench gate structure, the barrier structure, and the first-1 trench gate structure are arranged in this order in the first direction.

### (Appendix 3)

The semiconductor device according to Appendix 1 or 2, wherein
the first lower electrode of the barrier structure extends through the insulating film to a top of the first trench and is electrically connected to the one of the gate electrode and the dummy electrode.

### (Appendix 4)

The semiconductor device according to Appendix 1, further comprising
a diode region provided to the semiconductor substrate, wherein
one of the diode region, one of the first-2 trench gate structure, one of the barrier structure, the first-1 trench gate structure, another of the barrier structure, another of the first-2 trench gate structure, and another of the diode region are arranged in this order in the first direction.

### (Appendix 5)

The semiconductor device according to any one of Appendices 1 to 4, wherein
the insulating film of the barrier structure is provided entirely between the first-1 upper electrode and the first-2 upper electrode.

### (Appendix 6)

The semiconductor device according to any one of Appendices 1 to 5, wherein
at least any one of a portion in contact with a side and a bottom of the first-1 upper electrode and a portion in contact with a side and a bottom of the first-2 upper electrode of the insulating film of the barrier structure is rounded in a cross-sectional view.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate having a first trench, a second trench, and a third trench, the first trench extending in a first direction, the second trench extending along the first trench in the first direction, the third trench extending in a second direction different from the first direction and being connected to the first trench and the second trench;
a first-1 trench gate structure and a first-2 trench gate structure provided in the first trench;
a barrier structure provided in the first trench and between the first-1 trench gate structure and the first-2 trench gate structure;
a second trench gate structure provided in the second trench; and
a third trench gate structure provided in the third trench and connected to the first-2 trench gate structure and the second trench gate structure, wherein
the first-1 trench gate structure comprises:
a first lower electrode; and
a first-1 upper electrode insulated from the first lower electrode and provided above the first lower electrode,
the first-2 trench gate structure comprises:
the first lower electrode; and
a first-2 upper electrode insulated from the first lower electrode and provided above the first lower electrode,
the barrier structure comprises:
the first lower electrode; and
an insulating film provided at least partially between the first-1 upper electrode and the first-2 upper electrode and insulating the first-1 upper electrode and the first-2 upper electrode,
the second trench gate structure comprises:
a second lower electrode; and
a second upper electrode insulated from the second lower electrode and provided above the second lower electrode,
the third trench gate structure comprises:
a third lower electrode electrically connecting the first lower electrode and the second lower electrode; and
a third upper electrode electrically connecting the first-2 upper electrode and the second upper electrode, insulated from the third lower electrode, and provided above the third lower electrode,
the first lower electrode, the second lower electrode, the third lower electrode, the first-2 upper electrode, the second upper electrode, and the third upper electrode are electrically connected to one of a gate electrode and a dummy electrode, and
the first-1 upper electrode is electrically connected to the other one of the gate electrode and the dummy electrode.

2. The semiconductor device according to claim 1, further comprising
a lower-stage lifting structure which is provided in the first trench and in which the first lower electrode extends to a top of the first trench, wherein
the lower-stage lifting structure, the first-2 trench gate structure, the barrier structure, and the first-1 trench gate structure are arranged in this order in the first direction.

3. The semiconductor device according to claim 1, wherein
the first lower electrode of the barrier structure extends through the insulating film to a top of the first trench and is electrically connected to the one of the gate electrode and the dummy electrode.

4. The semiconductor device according to claim 1, further comprising
a diode region provided to the semiconductor substrate, wherein
one of the diode region, one of the first-2 trench gate structure, one of the barrier structure, the first-1 trench gate structure, another of the barrier structure, another of the first-2 trench gate structure, and another of the diode region are arranged in this order in the first direction.

5. The semiconductor device according to claim 1, wherein
the insulating film of the barrier structure is provided entirely between the first-1 upper electrode and the first-2 upper electrode.

6. The semiconductor device according to claim 1, wherein
at least any one of a portion in contact with a side and a bottom of the first-1 upper electrode and a portion in contact with a side and a bottom of the first-2 upper electrode of the insulating film of the barrier structure is rounded in a cross-sectional view.
